(19) United States
(12) Patent Application Publication
(10) Pub. No.: US 2026/0164586 A1
(43) Pub. Date: Jun. 11, 2026

(54) AUTOMATION FIELD DEVICE

(71) Applicant: Endress+Hauser SE+Co. KG, Maulburg (DE)

(72) Inventors: Raphael Schonhardt, Rheinfelden (DE); Michael Lais, Schönau im Schwarzwald (DE); Vitogiuseppe Di Cosola, Hartheim (DE)

(21) Appl. No.: 19/103,792

(22) PCT Filed: Jul. 17, 2023
(86) PCT No.: PCT/EP2023/069789

§ 371 Date: Feb. 13, 2025

(30) Foreign Application Priority Data
Aug. 24, 2022 (DE) 10 2022 121 385.4

(51) Int. Cl. H05K 7/14

(52) U.S. Cl. CPC H05K 7/1462

(57) ABSTRACT

An automation field device includes: a field device housing; arranged in the field device housing, a field device electronics unit having at least one circuit board; arranged in the housing, a circuit board holder for holding the circuit board, wherein the circuit board holder has an engagement mechanism for resistant fastening of the circuit board, wherein the circuit board has a counter-engagement mechanism corresponding to the engagement mechanism, wherein the engagement mechanism has a recess in a subregion of the outer contour of the circuit board holder, and the counter-engagement mechanism of the at least one circuit board has at least one engagement nose, wherein the recess and the engagement nose are fitted to one another such that the engagement nose can engage in the recess, wherein the engagement and counter-engagement mechanisms are located above a potting compound height such that the engagement and counter-engagement mechanisms are not potted.

The invention relates to a field device of automation technology as well as to a method for producing such a field device of automation technology.

Known from the state of the art are field devices, which are used in industrial plants. In process automation technology, as well as in manufacturing automation technology, field devices are often applied. Referred to as field devices are, in principle, all devices, which are applied near to a process and which deliver, or process, process relevant information. Field devices are used for registering and/or influencing process variables.

Serving for registering process variables are measuring devices, or sensors. Such are used, for example, for pressure- and temperature measurement, conductivity measurement, flow measurement, etc. and register the corresponding process variables, pressure, temperature, conductivity, pH value, fill level, flow, etc. Used for influencing process variables are actuators. Such are, for example, pumps or valves, which can influence the flow of a liquid in a tube or pipe or the fill level in a container. Besides the above mentioned measuring devices and actuators, referred to as field devices are also remote I/Os, radio adapters, and, in general, devices, which are arranged at the field level.

A large number of such field devices are manufactured and sold by the Endress+Hauser group of companies.

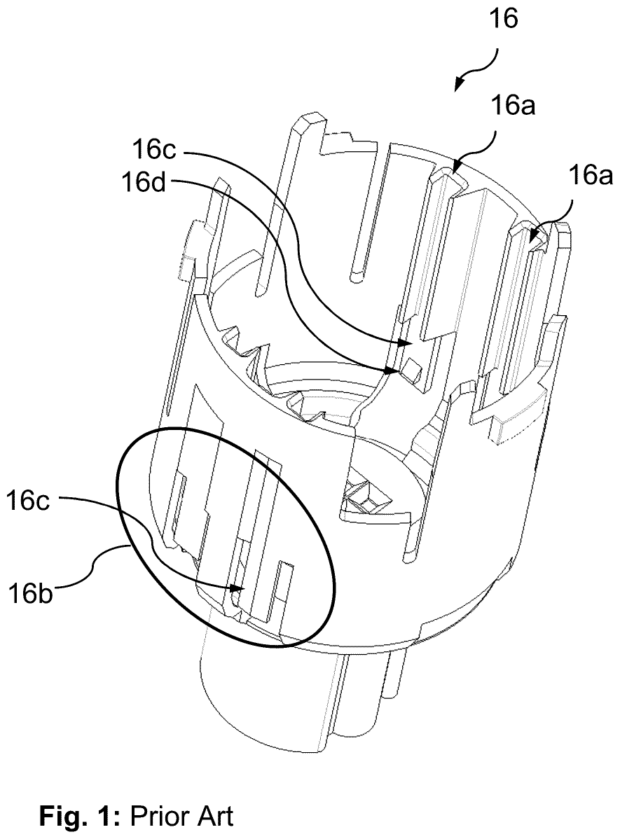

Such field devices have, especially, at least at times and/or at least sectionally in contact with a process medium, a sensor element, which serves for producing a signal dependent on the process variable. Furthermore, these devices have an electronics unit arranged in a housing, wherein the electronics unit serves for processing and/or forwarding signals, especially electrical and/or electronic signals, produced by the sensor unit. Typically, the electronics unit comprises a plurality of circuit boards with components arranged thereon. The circuit boards are usually arranged and mechanically secured in a circuit board holder. FIG. 1 shows such a circuit board holder, such as known in the state of the art. In the state of the art, it is presently usual for mechanical securement of the circuit boards to provide a releasable engagement or fixing mechanism located at the bottom of the circuit board holder for securing the circuit board to the circuit board holder. The arrangement of the engagement or fixing mechanism at the bottom of the circuit board holder is such that removal from a mold is possible. The engagement or fixing mechanism is usually implemented in such a manner that an elongated flexible arm extends from a side wall of the circuit board holder and has on a side toward the central axis of the circuit board holder a nose, which engages in a corresponding recess of the installed circuit board.

By embodiment and bottom-near arrangement of the engagement or fixing mechanism, the circuit board holder is penetrated at its outwardly facing side wall and is, thus, no longer sealed there. This lack of sealing means that in the case of potting processes, in the case of which the circuit boards mounted in the circuit board holder are poured over with a potting compound, e.g., silicone gel, it is not possible to do the pouring on the circuit board holder before introduction into the housing of the field device (preassembly of the circuit board holder), since the potting compound is not retained in the circuit board holder. For this reason, the circuit board holder needs first to be introduced in the housing, before the pouring, since then the housing can serve as outer mold for the circuit board holder, in order, thus, to prevent, at least partially, escape of the potting compound. In order to assure that the potting compound during its pouring on the circuit board holder installed in the housing does not leak into unintended regions of the housing, extra sealing measures are necessary in the housing and/or around the circuit board holder for the pouring. These additional measures lead, in turn, to increased costs and efforts for manufacturing. Furthermore, the potting compound requires more time for curing, the greater the amount of potting compound poured into the housing.

An object of the invention is, thus, to overcome these problems.

The object is achieved according to the invention by the field device of automation technology as defined in claim 1 and the method as defined in claim 7.

The automation field device of the invention comprises:
a field device housing;
arranged in the field device housing field device, an electronics unit having at least one circuit board;
arranged in the field device housing, a circuit board holder for holding the at least one circuit board of the field device electronics unit, wherein the circuit board holder with a surrounding outer contour is fitted at least in a subregion to an inner contour of the field device housing in such a manner that the outer contour of the circuit board holder lies essentially flushly against the inner contour of the field device housing, wherein the circuit board holder has in the subregion at least one engagement mechanism for resistant fastening of the at least one circuit board, wherein the at least one circuit board has a counter-engagement mechanism corresponding to the engagement mechanism of the circuit board holder, wherein the engagement mechanism of the circuit board holder has a recess in the subregion of the outer contour of the circuit board holder and the counter-engagement mechanism of the at least one circuit board has at least one engagement nose, wherein the recess and the engagement nose are fitted to one another in such a manner that the engagement nose can engage in the recess, wherein the at least one circuit board is installed in the circuit board holder and the circuit board holder holds the at least one circuit board as a result of engagement of the engagement and counter-engagement mechanisms, wherein the at least one circuit board is potted in the circuit board holder with a potting compound to a predetermined potting compound height, wherein the engagement and counter-engagement mechanisms are embodied in, or on, the circuit board holder and the at least one circuit board in such a manner that the engagement and counter-engagement mechanisms lie above the potting compound height, such that the engagement and counter-engagement mechanisms are not potted.

An advantageous embodiment of the automation field device of the invention can provide that the circuit board holder is embodied in the form of a cup.

Another advantageous embodiment of the automation field device of the invention can provide that, in the field device as above defined, the circuit board holder is embodied in such a manner that, up to the predetermined potting compound height, it has no opening in the outer contour.

In turn, another advantageous embodiment of the automation field device of the invention can provide that the at least one circuit board has at least two engagement noses, which are preferably formed on opposite sides of an end of the at least one circuit board installed in the circuit board holder. Especially, the embodiment can provide that the at least two engagement noses are embodied in such a manner that the circuit board holder is ovally deformed for installation of the circuit board in the circuit board holder (16).

Another advantageous embodiment of the automation field device of the invention can provide that the two engagement noses are formed diametrally opposite on a circuit board edge of the at least one circuit board, wherein the circuit board edge is located at an opposite end of the circuit board installed in the circuit board holder.

The invention relates further to a method for producing an automation field device according to at least one of the above described embodiments, comprising method steps as follows:
providing the field device housing;
providing the field device electronics unit with the at least one circuit board;
providing the circuit board holder for holding the at least one circuit board;
installing the at least one circuit board in the circuit board holder in such a manner that the engagement and counter-engagement mechanisms engage and thus secure the circuit board mechanically in the circuit board holder; and
installing the circuit board holder in the field device housing.

An advantageous form of embodiment of the method of the invention can provide that the at least one circuit board is potted in the circuit board holder with a potting compound to the predetermined potting compound height, before the circuit board holder is installed in the field device housing.

An alternative form of embodiment of the method of the invention can provide that the at least one circuit board is potted in the circuit board holder with a potting compound to the predetermined potting compound height, after the circuit board holder is installed in the field device housing.

The invention will now be explained in greater detail based on the appended drawing, the figures of which show as follows:

FIG. 1 a circuit board holder known in the state of the art, such as has commonly been applied in a field device of automation technology;

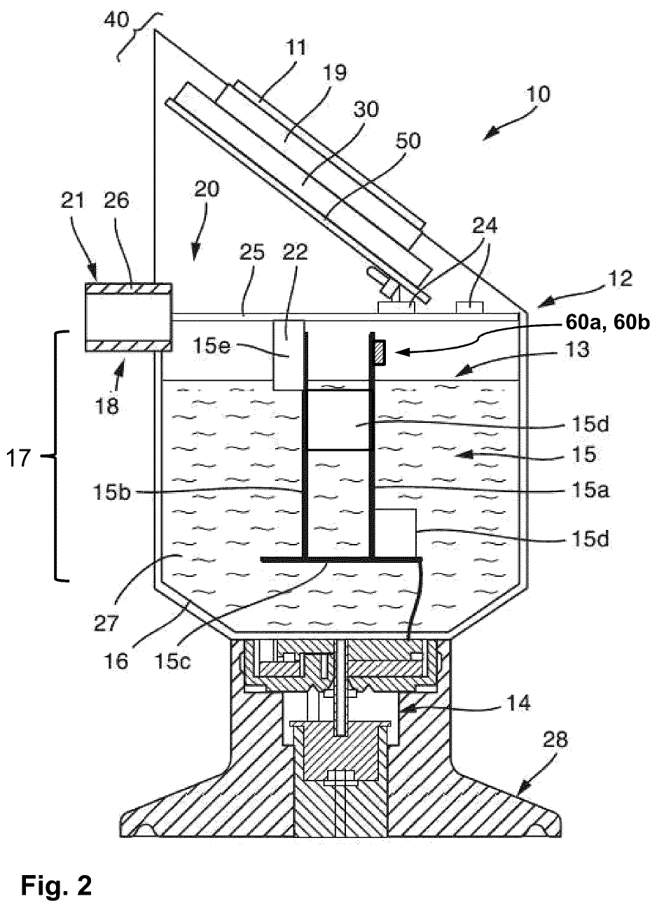

FIG. 2 by way of example, a sectional view of a field device of automation technology;

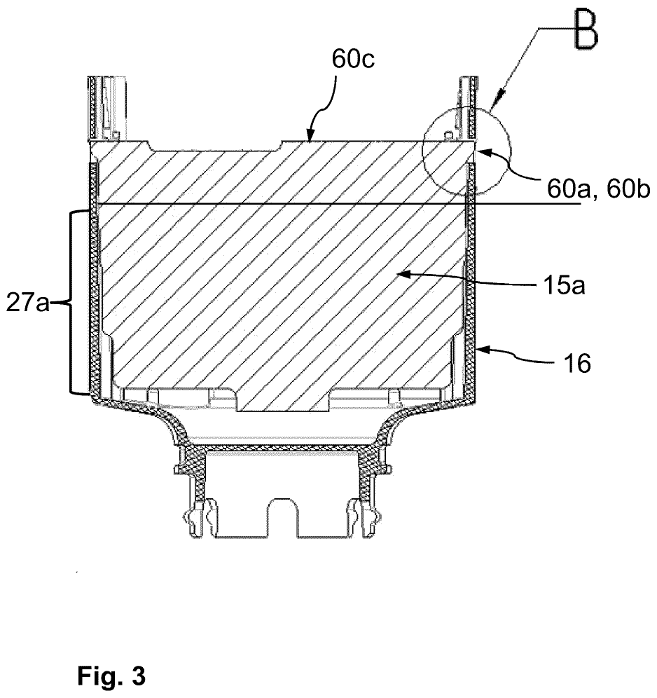

FIG. 3 a sectional view of a circuit board holder provided for use in a field device of automation technology, with, located therein, a circuit board retained in the circuit board holder by means of engagement and counter-engagement mechanisms, one set of which is located in the region B; and

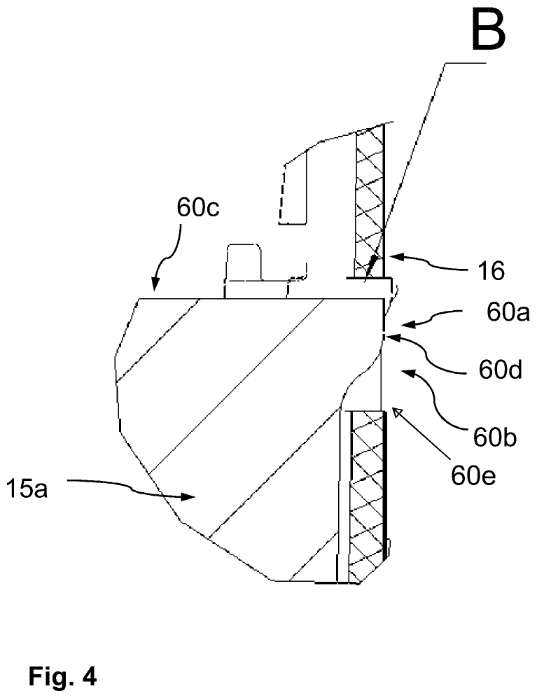

FIG. 4 a detail view of region B of the circuit board holder and the circuit board where the engagement and counter-engagement mechanisms are formed.

FIG. 1 shows a circuit board holder 16 known in the state of the art, such as commonly currently applied in a field device of automation technology 10. Circuit board holder 16 includes laterally placed guide rails 16a, which serve for receiving the circuit boards. Furthermore, the circuit board holder 16 includes, such as already described above, a releasable engagement or fixing mechanism 16b in the lower region, via which a circuit board (in FIG. 1 not separately shown) can be mechanically secured in the circuit board holder 16. The engagement or fixing mechanism 16b is, in such case, implemented in such a manner that two mutually opposing, elongated arms 16c are prepared from a side wall of the circuit board holder 16 during its production, such that the arms 16c have a certain flexibility. On a circuit board holder central axis facing side of each arm 16c, the circuit board holder 16 further includes a nose 16d, which engages a corresponding recess of an inserted circuit board.

This circuit board holder 16 was, until now, placed in the field device housing 12 and then filled with a potting compound 27. By placing the circuit board holder 16 in the housing 12, the “unsealed sites” (wall openings resulting from preparing the arms) were at least partially sealed by the tightly adjoining housing wall, such that the potting compound 27 remained in the circuit board holder 16. In order to prevent escape of the potting compound 27 into an inappropriate region of the field device housing 12, e.g. in the direction of an electronics unit arranged further below in the housing 12 and serving for processing and/or forwarding of signals produced by the sensor element 14, it can 17 be necessary, in given cases, that further sealing measures be implemented in the housing 12.

FIG. 2 represents, by way of example, a sectional view of a field device of automation technology. The field device, 10, includes a field device housing 12, which surrounds an inner space 13. Field device housing 12 includes an at least sectionally rotationally symmetric subregion 17, in which is located a circuit board holder 16 to be described in greater detail below.

Furthermore, the field device 10 includes: a sensor assembly arranged terminally in the field device housing 12 and having a sensor and/or actuator element 14 for setting and/or registering a process variable; and a process connection 28. Process connection 28 can be a screw thread type or a screwed or clampable flange.

The sensor and/or actuator element 14 in the present example of an embodiment comprises a fill level sensor element for registering a fill level as process variable. However, the invention is not limited to the type or particular embodiment of sensor and/or actuator element, but can, instead, be applied, in principle, to any kind of sensor- or actuator.

Serving in the inner space 13 of the field device housing for providing and/or conditioning a sensor and/or actuator signal is a field device electronics unit 15. Field device electronics unit 15 thus operates the sensor and/or actuator element 14.

In the present example of an embodiment, the field device electronics unit includes three circuit boards 15a, 15b, 15c. These are connected electrically together via corresponding plug and counter-plug connectors 15d. These can be embodied both as rigid as well as also flexible connectors. Also, the positions of the plug and counter-plug connectors can be reversed.

The field device electronics unit 15 further includes a fourth circuit board 25 serving as an interface electronics unit 20 and having a field contact plug 21, which is arranged in a longitudinal axis of the circuit board 25 on a circuit board edge and soldered to such. Through field contact plug 21, data, especially measured values, and/or energy can be transferred between the field device 10 and an external unit, for example, a superordinated unit or other field device. The field contact plug 21 it can be especially a plug/socket connector, for example, an M12-connector. In order to lead the field contact plug outwardly, the field device housing 12 includes a correspondingly formed housing opening 18. The fourth circuit board 25 can likewise be electrically connected with one of the other circuit boards via a plug and counter-plug connector 15e, 22. Furthermore, electronic components 24 for EMC and/or explosion protection measures can be applied on the circuit boards. 28

At an upper end of the field device 10, the field device housing 12 has a display 19 for display and/or interaction with the field device 10. The display can have capacitive keys for the interaction. Such can be implemented, for example, by a corresponding capacitive film. In order to meet hygienic requirements, the display can be arranged behind a viewing and touch screen 11 integrated in the housing 12 in the inner space 13 of the field device. In order to have a best possible view, and readability of information on the display 19 placed behind the viewing screen 11 and/or a friction free operation of the capacitive keys, the display 19 should contact the rear side of the viewing and touch screen 11 as planarly and/or uniformly as possible. Serving for this can be, for example, a display frame 30, which, on the one hand, receives the display, and, on the other hand, is placed correspondingly behind the viewing and touch screen 11.

Circuit boards 15a, 15b, 15c, 25 of the field device electronics unit 15 are arranged, at least partially, in a circuit board holder 16 and are mechanically secured by such. The circuit board holder is embodied with its outer contour in such a manner that it lies at least sectionally essentially flushly on an inner surface of the rotationally symmetric region of the housing.

In the example of an embodiment shown in FIG. 2, the circuit board holder 16 has a cuplike shape. For seating of the circuit boards, the circuit board holder 16 can have internal, lateral guide rails 16a, such also shown in FIG. 1. In such case, two, preferably diametrally oppositely arranged, guide rails 16a can be provided for receiving a circuit board. Furthermore, the circuit board holder 16 includes an engagement mechanism 60a for resistant fastening of the circuit board 15a. Circuit board 15a includes for this, in turn, a corresponding counter-engagement mechanism 60b. For each circuit board to be installed in the circuit board holder, matching engagement and counter-engagement mechanisms are present. In the example of an embodiment shown in FIG. 2, the positions of the engagement and counter-engagement mechanisms are shown, by way of example, only by a box with the reference characters 60a, 60b. The engagement and counter-engagement mechanisms are arranged in the upper region of the circuit board holder and circuit board, e.g., on the end far from the sensor and/or actuator element 14. Furthermore, the circuit boards 15a, 15b and 15c are potted in the circuit board holder with a potting compound 27.

FIG. 3 shows, by way of example, a sectional view of a circuit board holder 16 for a more detailed description of the engagement and counter-engagement mechanisms 60a, 60b, one set of which is located in the region B. Thus, arranged in the circuit board holder, by way of example, is a circuit board 15a, which is retained releasably in the circuit board holder 16 by means of the engagement and counter-engagement mechanisms 60a, 60b. Circuit board 15a is potted in the circuit board holder 16 to a predetermined potting compound height 27a by means of potting compound 27. Serving as potting compound can be, for example, SILGel silicone gel. Usually, the potting compound height 27a is determined in such a manner that the potting compound fills about half to two thirds of the volume of the circuit board holder 16. The engagement and counter-engagement mechanisms 60a, 60b are then arranged in the non-potted region of the circuit board holder 16 and the circuit board 15a. In the example of an embodiment shown in FIG. 3, the counter-engagement mechanism 60b is arranged at a circuit board edge 60c located on the trailing end of the circuit board 15a.

FIG. 4 shows, for this, a detail view of region “B” of FIG. 3, including the circuit board holder 16 and the circuit board 15a where one set of the engagement and counter-engagement mechanisms 60a, 60b are located. The counter-engagement mechanism 60b comprises two engagement noses 60d, which are preferably formed on opposite ends of the circuit board edge 60c. The engagement noses 60d can be made, for example, by milling a corresponding outer contour of the circuit board 15a. The engagement mechanism 60a of the circuit board holder 16 includes corresponding recesses 60e, in which the engagement noses 60d can engage upon the introduction, or insertion, of the circuit board 15a. The recesses 60e can be made, for example, by milling a cavity in the circuit board holder 16 or using a correspondingly embodied injection mold in the production of the circuit board holder by means of injection molding. The recesses 60e can, in such case, go through the lateral wall of the circuit board holder 16 at the location or alternatively be only a recess, which does not goes through the entire lateral wall at the location. The recesses 60e and the engagement noses 60d are fitted to one another in such a manner that the engagement noses 60d of the circuit board engage the recesses of the circuit board holder 16 and are secured there. Preferably, the engagement noses 60d are embodied in such a manner that for introducing the circuit board 15a the circuit board holder 16 must be slightly ovally compressed, until the engagement noses 60d engage the recesses 60e. After the engagement of the engagement noses 60d in the recesses 60e, there is no more stress on the circuit board holder, such that, as, for example, in the case of a snap connection, fatigue failure of the engagement can be avoided. As a result of the engagement and counter-engagement mechanisms 60a, 60b formed according to the invention, it is possible to pot the circuit board 15a with the potting compound 27 before introduction of the circuit board holder 16 into the field device housing 12. In this way, costs and complexity can be reduced, since no delicate arms need to be prepared in the side wall of the circuit board holder, such as usual in the state of the art.

List of Reference Characters

| | |
|---|---|
| 10 | field device of automation technology |
| 11 | viewing screen |
| 12 | field device housing |
| 13 | inner space |
| 14 | sensor and/or actuator element |
| 15 | field device electronics unit |
| 15a-15c | circuit boards |
| 15d | plug and counter-plug connectors |
| 15e | plug connector |
| 16 | circuit board holder |
| 16a | lateral guide rails of the circuit board holder |
| 16b | engagement or fixing mechanism according to the state of the art |
| 16c | arm of the circuit board holder according to the state of the art |
| 16d | nose of the circuit board holder according to the state of the art |
| 17 | rotationally symmetric subregion |
| 18 | housing opening |
| 19 | display |
| 20 | interface electronics unit |
| 21 | field contact plug |
| 22 | counter-plug connector of the interface electronics unit |
| 24 | electronic components, for example, for EMC- and/or Ex- |
| | protective measures |
| 25 | another circuit board |
| 26 | plug socket for field contact plug |
| 27 | potting compound |
| 27a | predetermined potting compound height of potting compound on |
| | the circuit board in the circuit board holder |
| 28 | process connection |
| 30 | display frame |
| 40 | display holder |
| 50 | support plate, or circuit board |
| B | detail view of the engagement and counter-engagement |
| | mechanisms |
| 60a | engagement mechanism of the circuit board holder, especially |
| | engagement nose |
| 60b | counter-engagement mechanism of the circuit board, especially |
| | recess |
| 60c | circuit board edge where the engagement mechanism is formed |
| 60d | engagement noses of the circuit board |
| 60e | recesses of the circuit board holder |

1-9. (canceled)

10. A process automation field device, comprising:
a field device housing;
a field device electronics unit including at least one circuit board and disposed in the field device housing;
a circuit board holder disposed in the field device housing and configured to hold the at least one circuit board,
wherein the circuit board holder with a surrounding outer contour is fitted, at least in a subregion, to an inner contour of the field device housing such that the outer contour of the circuit board holder lies essentially flushly against the inner contour of the field device housing,
wherein the circuit board holder includes, in the subregion, at least one engagement mechanism configured to secure the at least one circuit board,
wherein the at least one circuit board includes a counter-engagement mechanism corresponding to an engagement mechanism of the least one engagement mechanism of the circuit board holder,
wherein the corresponding engagement mechanism includes a recess in the subregion of the outer contour of the circuit board holder, and the counter-engagement mechanism of the at least one circuit board includes at least one engagement nose,
wherein the recess and the at least one engagement nose are fitted to each other such that at least one engagement nose can engage in the recess,
wherein the at least one circuit board is introduced in the circuit board holder, and the circuit board holder holds the at least one circuit board by engagement of the corresponding engagement and counter-engagement mechanisms,
wherein the at least one circuit board is potted in the circuit board holder with a potting compound to a predetermined potting compound height, and
wherein the corresponding engagement and counter-engagement mechanisms are configured in, or on, the circuit board holder and the at least one circuit board, respectively, such that the corresponding engagement and counter-engagement mechanisms lie above the potting compound height and thereby are not potted.

11. The field device as claimed in claim 10, wherein the circuit board holder is embodied in the form of a cup.

12. The field device as claimed in claim 10, wherein the circuit board holder is embodied such that, up to the predetermined potting compound height, there is no opening in the outer contour.

13. The field device as claimed in claim 10, wherein the at least one circuit board includes at least two engagement noses.

14. The field device as claimed in claim 13, wherein the at least two engagement noses are disposed on opposite sides of an end of the at least one circuit board introduced into the circuit board holder.

15. The field device as claimed in claim 13, wherein the at least two engagement noses are embodied such that the circuit board holder is ovally deformed for installing the circuit board in the circuit board holder.

16. The field device as claimed in claim 13, wherein the at least two engagement noses are formed diametrally opposite on a circuit board edge of the at least one circuit board, and wherein the circuit board edge is at an opposite end of the circuit board as introduced into the circuit board holder.

17. A method for manufacturing the automation field device as claimed in claim 10, comprising method steps as follows:
providing the field device housing, the field device electronics unit with the at least one circuit board, and the circuit board holder configured to hold the at least one circuit board;
introducing the at least one circuit board into the circuit board holder such that the corresponding engagement and counter-engagement mechanisms engage and thereby secure the at least one circuit board mechanically in the circuit board holder; and
installing the circuit board holder into the field device housing.

18. The method as claimed in claim 17, further comprising potting the at least one circuit board in the circuit board holder with the potting compound to the predetermined potting compound height, before the circuit board holder is installed into the field device housing.

19. The method as claimed in claim 17, further comprising potting the at least one circuit board in the circuit board holder with the potting compound to the predetermined potting compound height, after the circuit board holder is installed into the field device housing
